(19) United States
(12) Patent Application Publication
(10) Pub. No.: US 2015/0147680 A1
(43) Pub. Date: May 28, 2015

(54) HIGHLY FUNCTIONAL COMPOSITE NANOPARTICLES AND METHOD FOR PRODUCING SAME

(71) Applicant: KOREA INSTITUTE OF INDUSTRIAL TECHNOLOGY, Cheonan-si (KR)

(72) Inventors: Han-Shin Choi, Incheon (KR); Hye-Sook Joo, Seoul (KR); Chul-Woong Han, Cheonan-si (KR)

(21) Appl. No.: 14/402,443

(22) PCT Filed: Mar. 26, 2013
(86) PCT No.: PCT/KR2013/002480

§ 371 Date: Dec. 1, 2014

(30) Foreign Application Priority Data
May 22, 2012 (KR) 10-2012-0054309

(51) Int. Cl. C23C 14/22; C23C 14/18; H01F 1/01; C04B 35/56; C23C 14/34; C09K 11/77; C23C 14/06; H01M 4/92

(52) U.S. Cl. CPC C23C 14/223; C23C 14/0635; C23C 14/18; H01M 4/926; C04B 35/5626; C23C 14/34; C09K 11/77; H01F 1/01
USPC 429/524; 427/215; 427/217; 51/307; 204/192.15; 429/535; 252/301.5; 252/62.55

(57) ABSTRACT

The present invention relates to highly functional composite nanoparticles including a support body formed of nanoparticles and first phase nanoparticles which are condensed on the surfaces of the support body particles after being evaporated through a physical vapor deposition process, and to a method for producing same. According to the present invention, a physical vapor deposition process is used instead of a wet process so as to produce eco-friendly composite nanoparticles that do not emit hazardous chemicals while having high economic feasibility and process reproducibility.

### BACKGROUND OF THE INVENTION

1. Field of the Invention

The present invention relates to highly functional nanoparticles, and more particularly, to highly functional composite nanoparticles which are produced in a manner in which first phase materials are condensed on surfaces of nano supports through a physical vapor deposition process, and a method for producing the same.

2. Description of the Related Art

Due to so-called ‘size effects’, nanoparticles exhibit completely new properties. Active researches are conducted for its applications in engineering aspect as well as industrial aspect. While studies on nanoparticles have generally focused on phenomena in pure substances and alloyed nanoparticles so far, demands are increasing for development of new substances that can meet needs from a variety of industrial fields by way of nano-attached particles of composite structure.

Because most nanoparticles are conventionally produced based on multi-stage wet process which can be rather complicated, disadvantages such as relatively lower economic feasibility or process reproducibility, and emission of hazardous chemical substances during process, have been experienced. Accordingly, it is necessary to develop a method of producing composite nanoparticles based on economic, and eco-friendly manufacturing method.

The nanoparticle technologies are applicable to, mainly, catalytic nanoparticles, abrasives, and rare earth phosphors.

The catalytic substances are applicable to a variety of industries. A representative example is the platinum (Pt) catalysts for use in fuel cells. In polymer fuel cells, hydrogen oxidation reaction and oxygen reduction reaction occur in the presence of Pt as a catalyst.

Considering that the catalytic reaction itself and catalysis rate and stability of catalyst directly lead into performances of MEA and deposits, performance of the fuel cells and economic feasibility and durability thereof heavily depend on Pt. Despite considerable development made in the Pt catalyst technology so far, many shortcomings still have to be resolved to achieve industrialization. Among these, it is particularly necessary to develop a technology that can satisfy both the requirement for light, thin, short, small features and requirement for durability in use, by way of decreased use of Pt and subsequently increased economic feasibility, and high density output.

Pt catalyst researches for reduced use of Pt are based on catalytic characteristics of Pt and mechanism that degrades Pt catalysts. That is, the basis of the researches for reduced use of Pt catalyst consists of methods for further activating catalytic reaction or achieving catalytic reaction using non-Pt elements, and methods for inhibiting degradation of catalytic reaction. It is necessary to enhance techniques to control grain refinement and grain size distribution in order to increase catalytic activity. For example, in the conventional precipitation and reduction method which involves use of Pt/C nano-catalysts, increased Pt content in the surfaces of carbon black causes increased average grain size of Pt, and enlarged grain size distribution leads into increasing Pt charge transfer rate and subsequently degraded electrochemical active surface area (ESA). That is, control on grain size and distribution thereof is rather inefficient due to increased charge transfer rate of Pt.

Degraded Pt reaction is the cause of degradation of not only Pt itself and but also support. The polymer electrolytic fuel cells are placed in extreme environment of high acidity, high electrical current and voltage gradient, oxidized environment, and so on, which can cause Pt to dissolve. Degradation of Pt leads into loss of Pt, due to dissolution of Pt, growth of the dissolved Pt with other Pt particles, or growth of Pt on interfaces between electrodes and polymer electrolytes or within polymer electrolytes. The natural gas-modified fuel can also have degraded catalytic activity as carbon monoxide (CO) in the modified fuel induces CO poisoning of Pt catalyst. That is, due to characteristic of Pt which binds stronger to CO, presence of CO in fuel gas can lead into reduced catalytic efficiency in the hydrogen oxidation. Carbon supports can also have substantial loss of Pt because loss of carbon due to oxidation on the surfaces of the supports induces separation of dispersed-attached Pt particles from the support surfaces and the Pt particles separated from the supports do not participate in catalytic reaction anymore.

The Pt catalyst technology can be categorized into technology to reduce use of Pt and technology to develop non-Pt catalytic substances as complete replacements for Pt. As a representative example, metal (Fe, Co)/N/C catalytic substances and carbon-based catalytic substances including CoWC, MoWC are proposed as the non-Pt catalysts. However, none has proposed catalyst substances as complete replacements with comparable performance to that of Pt so far.

Researches on catalysts, who are working to reduce use of Pt, have made a great progress through a variety of studies on processing. The principal approach is based on the fact that catalysis occurs on the surfaces of Pt catalysts, and thus focus is on enlarging surface area of the catalysis by refining grain sizes and thus enlarging surface area per Pt unit mass. However, this poses another challenge in terms of durability, because refined grain size can be accompanied with increased driving force for particle growth and accelerated Pt degradation. Accordingly, it is necessary to provide methods for suppressing grain growth and grain size optimization in view of reliability of a system.

Effort is also made to develop technology to partially replace Pt by use of Pt-transition metal nano-catalysts, and to reduce use of Pt by way of increasing catalytic activity. For example, considering ruthenium (Ru) has strong affinity to hydroxyl group and tendency to oxidize CO to CO₂, Pt—Ru catalyst has been proposed as a means for inhibiting CO poisoning of Pt. However, because both Pt and Ru belong to Pt family, decomposition is rather uneasy and thus, there is shortcoming of reduced recyclability due to decreased recovery rate.

Meanwhile, researchers of catalyst substances for reduced Pt use study Pt catalysts and they also search for ways to enhance performance of supports. At present, the most widely used catalyst supports are carbon black supports, but carbon black supports suffer degradation of catalyticity due to oxidation occurring during use of the carbon black supports. Separation of Pt particles due to oxidation serves as a cause of degraded Pt usage efficiency, because Pt is made to be isolated electrically. However, despite continuing efforts to find carbon treatment technology to suppress oxidation of carbon, nano-catalyst technology that use carbon nanotubes or carbon nanofabric as supports, or technologies to utilize non-carbon supports such as titanium oxide (TiO), tungsten carbide (WC) or tungsten oxide (WO), none has developed technologies that can completely deal with the problems mentioned above.

The nanoparticle technology can also be applied in the chemical-mechanical planarization (CMP) process which is essentially required in the manufacture of semiconductor integrated circuits (ICs). In manufacturing semiconductor ICs, it is required to ensure abrasive that is optimal for changes in wiring materials, and thus it is required to provide nanoparticles with chemical stability and good wear property for abrasive in CMP process.

In CMP process, the abrasive for mechanical polishing varies depending on the materials subject for polishing, and polishing velocity and surface characteristics of the polishing surface vary depending on grain size and forms of the abrasive. Conventional recommendation was to use technology to control grain size and forms of the abrasive mainly with wet process, but it has limits because wet process requires that different materials be prepared by different processes depending on the characteristics of polished materials and polishing process.

Further, nanoparticle technology is applicable to rare earth phosphors.

Because rare earth elements as raw materials of fluorescent materials are produced in very limited countries, it is necessary to develop technologies to reduce use of rare earth elements. It is particularly necessary to develop processing technology to attach desired rare earth nanoparticles onto surfaces of the supports via eco-friendly processing, rather than conventional method of attaching particles to solid solution by wet type processing that is generally applied to the rare earth phosphors so far.

### DETAILED DESCRIPTION OF THE INVENTION

### Technical Object

The present invention has been made to overcome the problems of the prior art discussed above, and therefore, it is an object of the present invention to provide highly functional composite nanoparticles which are produced in eco-friendly manner so as not to emit hazardous chemicals while having high economic feasibility and process reproducibility, and a method for producing the same.

It is another object of the present invention to provide highly functional composite nanoparticles which are applicable to catalytic nanoparticles, abrasive for CMP process, and rare earth phosphors, and a method for producing the same.

It is yet another object of the present invention to provide catalytic substances of composite nanostructure with catalytic properties that are enhanced from conventional Pt/C composite substances, and good durability, and a processing technology to synthesize the same.

It is yet another object of the present invention to provide abrasive substances for CMP process with which it is possible to easily control grain size and forms of the abrasive irrespective of types of polished substance, and a method for producing the same.

Furthermore, it is an object of the present invention to provide rare earth phosphor substances in which it is possible to attach desired rare earth nanoparticles onto surfaces of the supports for solid solution processing thereof by eco-friendly processing, and a method for producing the same.

### Means to Solve the Object

In order to accomplish the above-mentioned objects, the present invention provides highly functional composite nanoparticles, comprising supports consisting of nanoparticles, and nanoparticles of first phase evaporated by physical vapor deposition (PVD) process and condensed on surfaces of support particles.

The first phase may consist of platinum (Pt) substance and the supports may consist of carbon (C) particles, which may form Pt/C structure catalyst for use in fuel cells.

The supports may consist of carbon particles and substance of the first phase consists of tungsten carbide (WC) substance, which may form WC/C structure abrasive for chemical-mechanical planarization (CMP) process.

The supports may consist of carbon particles and substance of the first phase may consist of tungsten substance. W/C structure may be formed as evaporated tungsten is condensed into nanoparticles on surfaces of the carbon particles, and WC/C structure abrasive for chemical-mechanical planarization (CMP) process may be formed by carburizing the W/C particles by heat treatment under reducing atmosphere.

The supports may consist of tungsten oxide particles and substance of the first phase may consist of rare earth metal substance, which may form rare earth phosphor material of rare earth/tungsten oxide structure.

The supports may consist of NdFeB powder particles, and substance of the first phase may consist of Dy substance, which may form rare earth magnet of Dy/NdFeB structure.

The present invention also provides highly functional composite nanoparticles, comprising supports consisting of nanoparticles, nanoparticles of second phase deposited on surfaces of the support particles by physical vapor deposition (PVD) process to enlarge surface area of the supports, and nanoparticles of first phase deposited, by PVD process, on surfaces of the supports to which the nanoparticles of the second phase are attached.

The supports may consist of carbon particles, substance of the second phase may consist of conductive ceramic substance, ITO/C structure is formed as the conductive ceramic substance in vapor state is condensed into nanoparticles on surfaces of the carbon particles, substance of the first phase may consist of platinum (Pt), and Pt-ITO/C structure catalyst for use in fuel cells may be formed as the Pt in vapor state is condensed into nanoparticles on ITO/C surfaces.

The conductive ceramic substance preferably comprises indium-tin oxide.

The present invention provides a method for producing highly functional composite nanoparticles, comprising evaporating substance of first phase by PVD process, and condensing the evaporated substance of the first phase into nanoparticles on surfaces of supports which consist of nanoparticles.

The supports may consist of carbon particles and substance of the first phase may consist of Pt substance, and Pt/C structure catalyst for use in fuel cell may be formed as evaporated Pt is condensed into nanoparticles on surfaces of the carbon particles.

Preferably, the carbon particles may be uniformly agitated during a process in which the evaporated Pt is condensed into the nanoparticles on the surfaces of the carbon particles.

The PVD process may consist of evaporation process which may be any of sputtering, laser, electron beam, and arc.

Preferably, the Pt may be introduced into the PVD process at 1 to 10 wt % loading rate in order to form the Pt/C catalyst for use in fuel cells.

More preferably, the Pt may be introduced into the PVD process at 1 to 7 wt % loading rate in order to form the Pt/C catalyst for use in fuel cells.

The supports may consist of carbon particles and substance of the first phase may consist of tungsten carbide substance, and WC/C structure catalyst for use in CMP process may be formed as evaporated tungsten carbide is condensed into nanoparticles on surfaces of the carbon particles.

The present invention provides a method for producing highly functional composite nanoparticles, comprising evaporating substance of second phase by PVD process, which form supports to which second phase nanoparticles are attached as the evaporated substance of the second phase is condensed into nanoparticles on surfaces of the supports consisting of nanoparticles, evaporating substance of first phase by PVD process, and condensing the evaporated substance of the first phase into nanoparticles on surfaces of the supports to which the second phase nanoparticles are attached.

The supports may consist of carbon particles, and the substance of the second phase may consist of conductive ceramic substance. ITO/C structure supports may be formed as evaporated conductive ceramic substance is condensed into nanoparticles on surfaces of the carbon particles. The substance of the first phase may consist of Pt substance, and Pt-ITO/C structure catalyst for use in fuel cells may be formed as evaporated Pt is condensed into nanoparticles on surfaces of ITO/C supports.

### Effect of the Invention

According to highly functional composite nanoparticles configured as explained above and a producing method thereof, it is possible to produce composite nanoparticles which have high economic feasibility and process reproducibility and are eco-friendly that do not emit hazardous chemicals, by employing physical vapor deposition (PVD) process instead of wet process.

Further, according to the present invention, it is possible to produce catalytic substances of composite nanostructure with catalytic properties that are enhanced from conventional Pt/C composite substances, and good durability.

Further, according to the present invention, it is possible to produce abrasive substances for CMP process with which it is possible to easily control grain size and forms of the abrasive irrespective of types of polished substance.

Further, according to the present invention, it is possible to produce rare earth phosphor substances in which it is possible to attach desired rare earth nanoparticles onto surfaces of the supports for solid solution processing thereof by eco-friendly processing.

### BRIEF DESCRIPTION OF THE DRAWINGS

The above and/or other aspects and advantages of the present invention will become apparent and more readily appreciated from the following detailed description, taken in conjunction with the accompanying drawings of which:

FIG. 1 is photograph of Pt/C nano-catalyst synthesized by physical vapor deposition (PVD) technology according to the present invention;

FIGS. 2 and 3 are photographs of Pt/C nano-catalyst (10 wt % & 40 wt %, Johnson & Matthey) synthesized according to conventional technology;

FIGS. 4 and 5 are graphs of distribution of Pt/C nano-catalyst particles of FIGS. 1 to 3 and Pt nanoparticle number density;

FIG. 6 is a graph based on results of electrochemical property evaluation between Pt/C nano-catalyst of FIG. 1 and commercially-available Pt/C nano-catalyst (Johnson & Matthey) of FIGS. 2 and 3;

FIG. 7 is a schematic view of composite nanoparticle structure in which Pt nanoparticles are deposited on the surfaces of carbon particles, and composite nanoparticle structure in which second phase nanoparticles are deposited first on the surfaces of carbon particles thus enlarging surface area, followed by depositing of Pt nanoparticles;

FIGS. 8 to 10 are TEM and STEM photographs representing structure in which indium-tin oxide is deposited on the surface of carbon supports, and EDS analysis graph;

FIGS. 11 and 12 are TEM and STEM photographs of Pt-ITO/C composite catalysts prepared by applying conductive ceramic substance as the second phase, and EDS analysis graph;

FIG. 13 is EDS analysis graph;

FIGS. 14 and 15 are TEM and STEM photographs representing structure in which tungsten is deposited on the surfaces of carbon supports; and

FIG. 16 is STEM photograph representing structure in which tungsten carbide nanoparticles are formed on the surfaces of carbon supports via carburization on carbon supports with tungsten particles deposited thereon.

### BEST MODE

Highly functional composite nanoparticles and a method for producing the same according to preferred embodiments of the present invention will be explained in detail with reference to the accompanied drawings.

The highly functional composite nanoparticles according to the present invention are produced using eco-friendly physical vapor deposition (PVD) technique instead of conventional wet processing.

The PVD technique may involve evaporation of materials subject for coating with a variety of heat sources, which form nanoparticles or thin film in the process of condensation, or synthesis of nanoparticles or thin film via sputtering phenomenon using low temperature plasma. Because the PVD technique utilizes phase changing process, unlike wet processing or chemical vapor deposition (CVD) techniques, it is considered to be eco-friendly as it is able to fundamentally prevent generation of harmful substances during processing.

The highly functional composite nanoparticles according to the present invention are particularly applicable to catalytic nanoparticles that are produced via PVD technique, or to abrasive for CMP process or rare earth phosphors. Hereinbelow, highly functional composite nanoparticles will be explained in detail with reference to examples.

### Example 1

First, it is noted that the present invention is applicable to catalytic nanoparticles that are produced with PVD technique, and more particularly, is applicable to Pt catalysts for use in fuel cells.

To reduce use of Pt, grain miniaturization and grain size distribution control are critical for the technology of Pt catalysts for use in fuel cells. That is, because the sites of catalytic reaction are on the surfaces of the Pt catalysts, it is important to enlarge surface area of the catalytic reaction by miniaturizing sizes of the particles to thus enlarge surface area per Pt unit mass.

Further, it is necessary to adopt methods to suppress growth of the particles and achieve optimized grain size to control Pt degradation as Pt degrades due to miniaturization of the particles.

According to the present invention, Pt/C nano-catalyst is synthesized using PVD processing technology, and more specifically, Pt is evaporated by arc plasma, and gaseous Pt is condensed on the surfaces of the carbon, during which nanoparticles are formed. According to the present invention, it is desired to uniformly agitate base material powder, because unlike the conventional thin film lamination process, deposition is made on the surface of the powder particles.

FIGS. 1 to 5 show result of comparison between Pt/C nano-catalyst synthesized according to PVD processing technology of the present invention, and Pt/C nano-catalyst synthesized of the conventional technology. In this embodiment, characteristics of Pt/C nano-catalyst synthesized by application of deposition processing technology using arc plasma are illustrated, although the PVD processing technology of the present invention may apply a variety of evaporation processes that involve use of high density energy source such as sputtering, laser, electron beam, arc, or the like. Upon generating of pulse arc with respect to Pt electrode, Pt evaporation occurs, and accordingly, the evaporated Pt is deposited on the surfaces of the agitated carbon in the form of nanoparticles.

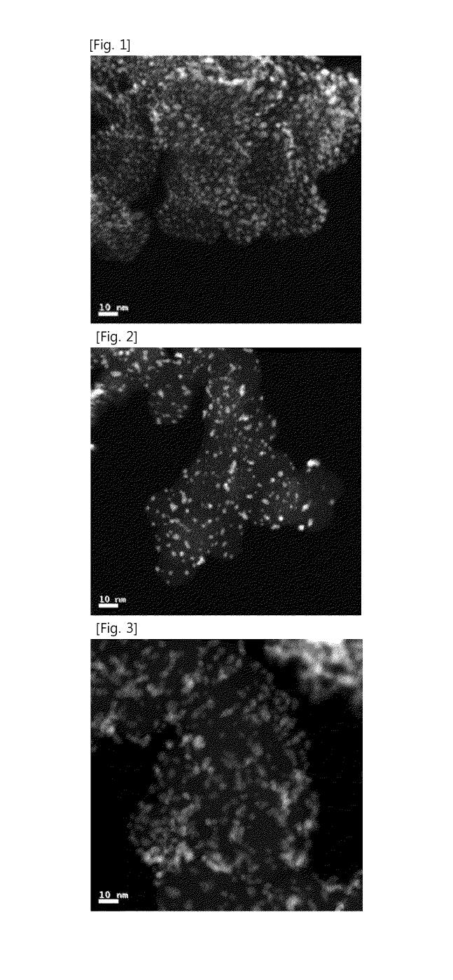

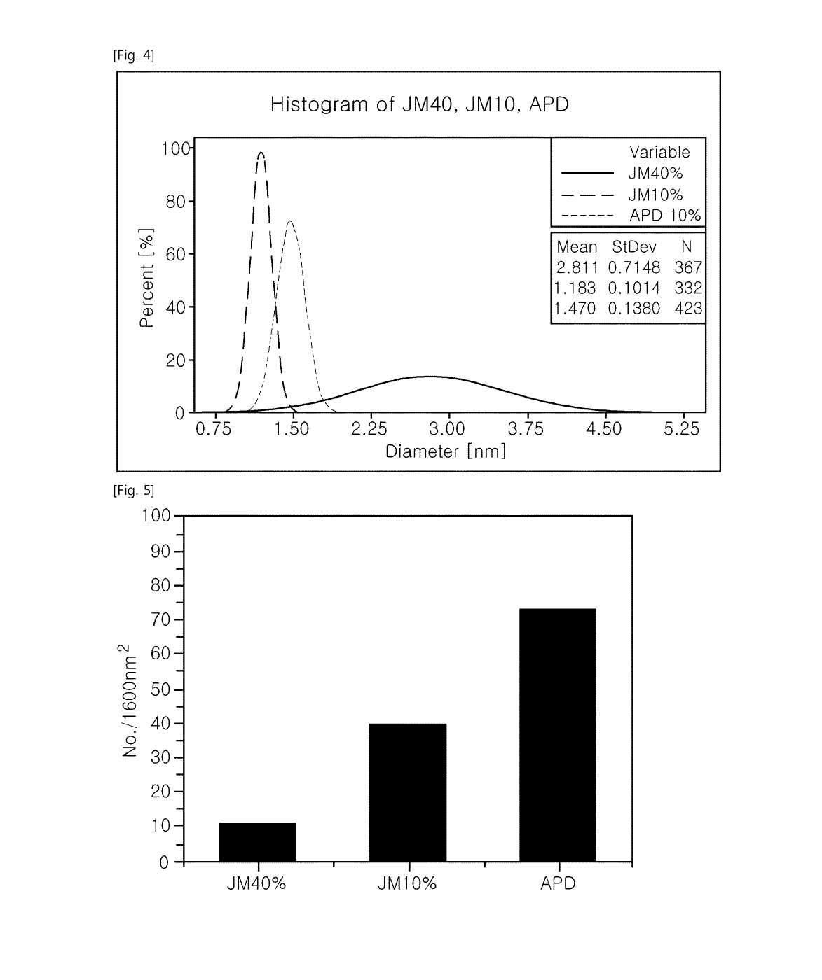

Referring to FIGS. 1 and 4, arc plasma Pt/C nano-catalyst has uniform formation of Pt particles having 5 wt % of Pt loading rate, and 1.5 nm of mean grain size. Referring also to FIG. 5, measurement of number density of Pt nanoparticles deposited on the carbon particle surfaces indicated average number of approximately 75 Pt particles per 1,600 nm². Referring to FIGS. 2 to 5, the commercially-available nano-catalyst (Pt nano-catalyst, Johnson & Matthey) exhibits characteristics of, with 10 wt % Pt loading rate, small grain size and narrow grain size distribution, but very low number density of Pt particles, and with catalyst having 40 wt % Pt loading rate, growth and condensation of Pt particles. Accordingly, it is revealed that minute Pt nanoparticles with narrow grain size distribution and high number density can be effectively synthesized in the Pt/C nano-catalyst that is synthesized according to arc plasma process.

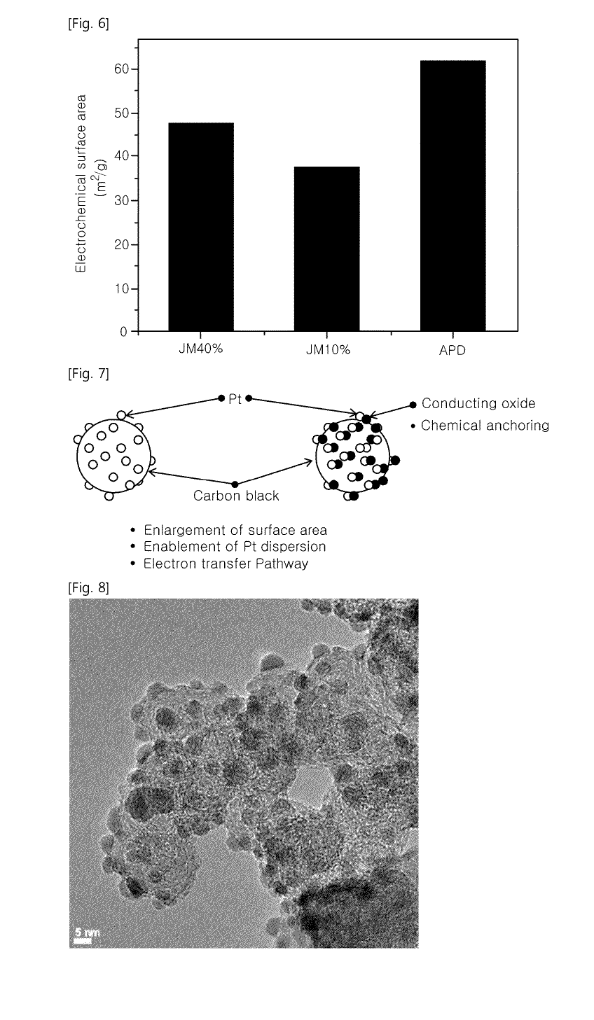

FIG. 6 illustrates result of electrochemical property evaluation on Pt/C nano-catalyst of FIG. 1 and commercially-available, Pt/C nano-catalyst (Johnson & Matthey) of FIGS. 2 and 3. To evaluate catalytic properties, cyclic voltametry was adopted to measure electrochemical active surface area (ESA), after which the measurements were compared with those of also commercially-available 10 wt % Pt/C and 40 wt % Pt/C (Johnson & Matthey). In order to measure C-V, electrode was prepared by synthesizing Pt/C ink (EOH: Nafion: PtC) and placing 30 mg slurry on glassy carbon base material (3 mm diameter) and drying the same.

For the prepared catalyst electrode, electrolyte of 0.5 H₂SO₄ liquid was used, and Ag/AgCl was used as reference electrode, and Pt was used as counter electrode. Polarization was done by cycle scan in −0.2 to 0.8 V range, and at 20 mV/s voltage polarization velocity. Electrode reaction occurred in the course of anodic and cathodic polarization voltage cycles from the open cell potential, and hydrogen desorption and Pt oxidation occurred in the anodic polarization, while Pt reduction and hydrogen adsorption occurred in the cathodic polarization. Based on the results illustrated in FIG. 6, it was confirmed that the Pt/C catalyst synthesized by arc plasma deposition had higher ESA than commercially-available catalyst.

As explained above, the Pt/C nano-catalyst formed by PVD process has enlarged physical surface area and ESA compared to Pt loading rate, because minute nanoparticles are uniformed dispersed. Meanwhile, although catalytic characteristics of the Pt/C nano-catalyst increases according to Pt loading rate, according to the present invention, it is preferred that the Pt loading rate is set to a range of 1 to 10 wt %, or more preferably, set to a range of 1 to 7 wt %.

When the Pt loading rate exceeds 7 wt %, number density of deposited Pt particles increases, thus leading into agglomeration by the collision among Pt particles. When the Pt loading rate exceeds 10 wt %, Pt can be coated on the surface of carbon, which in turn causes reduced surface area of reaction compared to Pt loading rate. When Pt loading rate is less than 1 wt %, effective Pt particles are insufficient so that performance of catalytic reaction velocity can degrade or even worse, the reaction may not occur at all.

### MODES FOR CARRYING OUT THE INVENTION

As suggested above in Example 1, in order to increase catalytic characteristics of the Pt/C catalyst, it is necessary to develop a method for increasing pt loading rate, while keeping Pt particles on the surface of the carbon in nanoparticle form.

To this end, Example 2 applies a method of enlarging surface area of the carbon supports by keeping Pt in nanoparticle form, and at the same time, increasing Pt loading rate. In order to enlarge surface area of the carbon supports, a method of depositing second phase nanoparticles is used. That is, in the nanoparticle-attached carbon supports which are synthesized by depositing second phase nanoparticles on the surface of the carbon, the presence of second phase nanoparticles enlarges surface area of the supports. The second phase nanoparticle can be deposited by evaporating second phase via PVD process and depositing the evaporated, second phase nanoparticles on the surface of the carbon. It is possible to increase Pt loading rate by depositing Pt on the nanoparticle-attached carbon supports with enlarged surface area by the process mentioned above, via arc plasma deposition process.

FIG. 7 illustrates composite nanoparticle structure (Example 1) in which Pt nanoparticles are deposited on the surfaces of carbon particles, and composite nanoparticle structure (Example 2) in which second phase nanoparticles are first deposited on the surfaces of the carbon particles to thus enlarge surface area, followed by deposition of Pt nanoparticles thereon.

Referring to FIG. 7, the Pt/C catalyst of Example 1 has such a structure in which Pt nanoparticles are dispersed and immobilized on the surfaces of the carbon supports, so that the content of the attached Pt nanoparticles depend on the surface area of the carbon supports. Accordingly, it is desirable to apply a method of enlarging physical surface area of the carbon supports as in the case of Example 2, in order to increase loading rate of the Pt particles.

Meanwhile, a method of varying causes of forming carbon, or a method of enlarging area of depositing pt particles with second phase, may be employed to enlarge surface area of the supports. While nanoparticles are attached to the supports, the supports also serve as a pathway for the electrons to move in the electrode. It is thus necessary to select the second phase substances that have high conductivity and good corrosion resistance. In the present invention, the conductive ceramic substance may be applied as the second phase. According to the addition of the second phase, when the Pt is deposited by PVD process, the physical surface area of the supports increases, Pt dispersion is enhanced, and additionally, Pt growth is suppressed in terms of both physical and chemical characteristics.

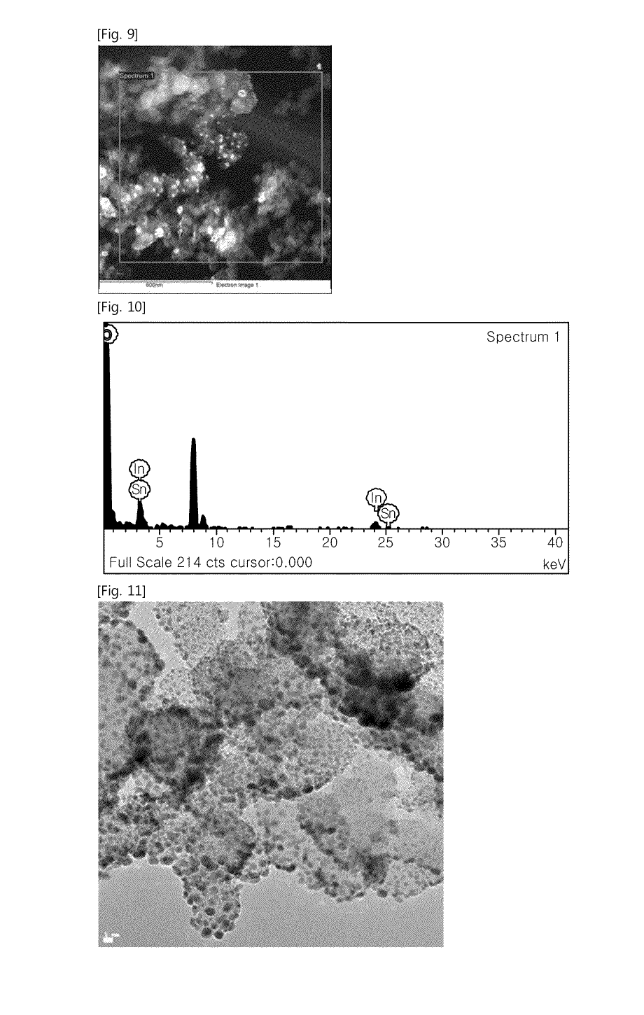

FIGS. 8 and 9 show photographs of test of adding conductive ceramic substance (i.e., indium-tin oxide (ITO)) as a second phase and depositing the second nanoparticles on the surface of the carbon supports. FIG. shows EDS result. The ITO nanoparticles exhibit a pattern in which particle number density increases in accordance with increasing cumulative number of arc pulses, and it is also observable that ITO nanoparticles are uniformed dispersed on the carbon surfaces with uniform grain size distribution.

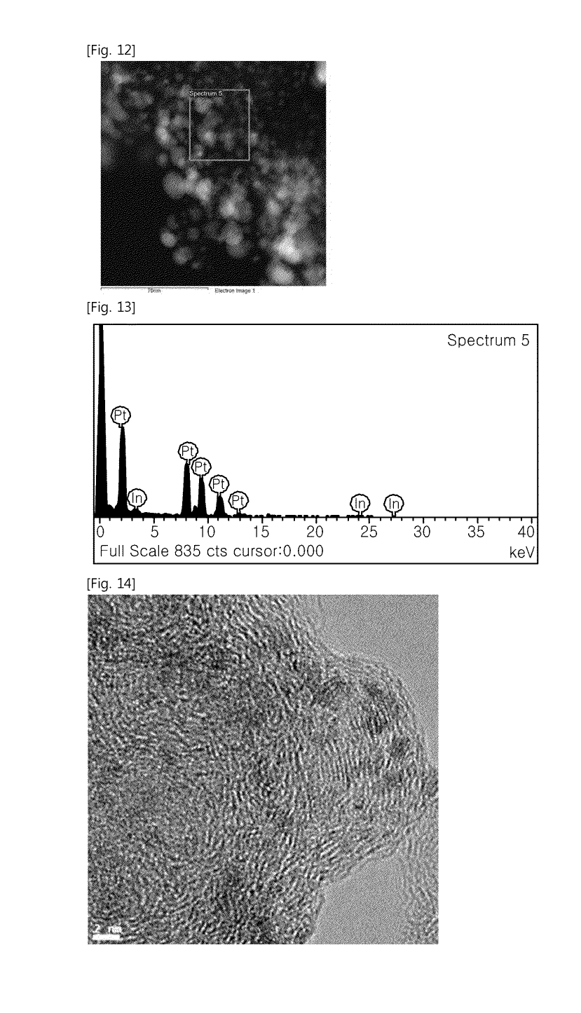

FIGS. 11 and 12 show photographs of test of preparing Pt-ITO/C composite catalyst using conductive ceramic substance as the second phase, and FIG. 13 shows EDS results. That is, Pt-ITO/C composite catalyst was formed by evaporating ITO substance with PVD process, followed by evaporation of Pt substance using arc plasma deposition process and condensation of evaporated Pt nanoparticles on the surfaces of the IPO/C supports. As a result of performing arc plasma vacuum deposition using Pt electrode, while mechanically agitating the ITO/C supports, it was observed that the Pt loading rate increased according to increasing number of pulsed arc and that Pt particles are deposited in uniform grain size distribution on the surfaces of the carbon particle surfaces and ITO nanoparticle surfaces.

That is, by forming second phase nanoparticles on the surfaces of the carbon supports in the synthesis of catalysts using PVD process as described above, when Pt or other element or alloy thereof is additionally deposited by PVD process, the physical surface area of the supports is increased, and when the second phase nanoparticles are used as catalyst, performance of the catalyst is kept from being degraded because of chemical combination or physical barrier effect. Other substances with good chemical durability may be applied as the second phase, instead of conductive ceramic.

### Example 3

Tungsten carbide may be used instead of the conductive ceramic for the second phase substance to enlarge surface area of the carbon supports. When formed on the surfaces of the carbon supports, the tungsten carbide nanoparticles provide effect because the tungsten carbide nanoparticles have catalytic activity themselves. For example, because tungsten carbide can activate oxidation of carbon monoxide, it is possible to enlarge surface area of the reaction by way of dispersion-attaching tungsten carbide nanoparticle catalysts using carbon supports.

The carbon particles with tungsten carbide nanoparticles deposited thereon as proposed by the embodiment of the present invention are applicable to not only tungsten carbide catalyst application, but also abrasive for semiconductor CMP process that utilizes high hardness and chemical durability of tungsten carbide.

In order to deposit tungsten carbide nanoparticles on the carbon supports, it is possible to directly deposit the tungsten carbide on the carbon support surfaces using PVD or CVD process. It is also possible to form tungsten carbide by depositing tungsten on the carbon support surfaces using PVD or CVD process, and carburizing the deposited tungsten particles.

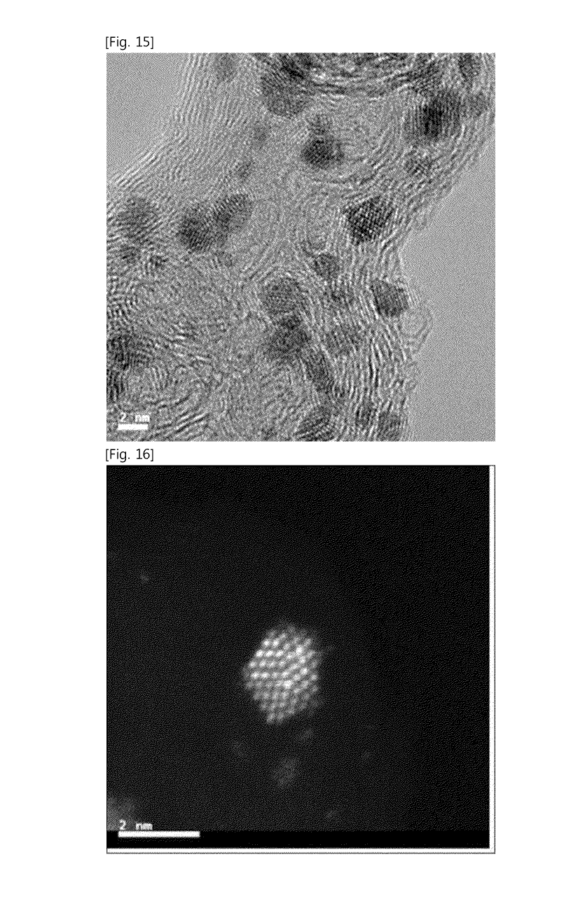

FIGS. 14 and 15 show photographs of test of depositing tungsten on the carbon support surfaces. The tungsten nano powders are formed on the carbon nano powder surfaces in uniform and minute manner, and it is possible to control the grain size and forms of the tungsten nanoparticles by adjusting tungsten deposition amount. Low tungsten content leads into synthesis of minute, almost sphere-like nanoparticles, while high tungsten content leads into synthesis of minute nanoparticles with angular nanoparticles, and transition of form occurs with grain size exceeding 4 nm.

Further, FIG. 16 shows photograph of carbon support surfaces with tungsten carbide nanoparticles formed thereon, as a result of carburization by PVD process with respect to the carbon supports with the tungsten particles deposited thereon. That is, with the tungsten nanoparticles deposited on the carbon support surfaces, the tungsten nanoparticles were carburized with heat treatment under reducing atmosphere. The carbon, which is support, serves as a source of carbon. The carburization reaction was done less than 10 minutes at reaction temperature of 1,000° C. In the process, it was observed by TEM analysis that effective phase change occurs into tungsten carbide. Growth of particles were observed before and after carburization heat treatment, and most of this is attributable for the expansion due to difference in molar volume ratio between tungsten and tungsten carbide, except for a few enlargement-related growth.

As explained above, the present invention proposes a processing technology of synthesizing nanoparticles in which conductive ceramic or tungsten carbide is deposited on carbon. The carbon nanoparticles with conductive ceramic nanoparticles deposited thereon, or carbon nanoparticles with tungsten carbide nanoparticles 5555555555555555+74deposited thereon, are themselves applicable industrially, or may be utilized as supports on which other catalytic nanoparticles are dispersed and immobilized.

Electrochemical reactivity and durability are the important factors for evaluating nano-catalyst. The Pt nanoparticles deposited by arc plasma deposition process are very fine nanoparticles and therefore, has very high driving force of the growth. At the same time, high number density allows relatively short transition distance in expansion and growth, which leads into high growth velocity. Accordingly, in order to deal with the above issue, the present invention applies carbon supports on which second phase nanoparticles are deposited, and accordingly provides effect of increasing Pt loading rate and effect of suppressing degradation of properties due to grain growth of the catalyst.

Those skilled in the art will appreciate that the conceptions and specific embodiments disclosed in the foregoing description may be readily utilized as a basis for modifying or designing other embodiments for carrying out the same purposes of the present invention. Those skilled in the art will also appreciate that such equivalent embodiments do not depart from the spirit and scope of the invention as set forth in the appended Claims.

### INDUSTRIAL APPLICABILITY

The present invention is applicable for highly functional composite nanoparticles produced in a manner of condensing first phase substance on the surface of nano supports by physical vapor deposition (PVD) process, and a method for producing the same.

What is claimed is:

1. Highly functional composite nanoparticles, comprising:
supports consisting of nanoparticles; and
nanoparticles of first phase evaporated by physical vapor deposition (PVD) process and condensed on surfaces of support particles.

2. The highly functional composite nanoparticles as set forth in claim 1, wherein the first phase consists of platinum (Pt) substance and the supports consist of carbon (C) particles, which form Pt/C structure catalyst for use in fuel cells.

3. The highly functional composite nanoparticles as set forth in claim 1, wherein the supports consist of carbon particles and substance of the first phase consists of tungsten carbide (WC) substance, which form WC/C structure abrasive for chemical-mechanical planarization (CMP) process.

4. The highly functional composite nanoparticles as set forth in claim 1, wherein the supports consist of carbon particles and substance of the first phase consists of tungsten substance,
W/C structure is formed as evaporated tungsten is condensed into nanoparticles on surfaces of the carbon particles, and
WC/C structure abrasive for chemical-mechanical planarization (CMP) process is formed by carburizing the W/C particles by heat treatment under reducing atmosphere.

5. The highly functional composite nanoparticles as set forth in claim 1, wherein the supports consist of tungsten oxide particles and substance of the first phase consists of rare earth metal substance, which form rare earth phosphor material of rare earth/tungsten oxide structure.

6. The highly functional composite nanoparticles as set forth in claim 1, wherein the supports consist of NdFeB powder particles, and
substance of the first phase consists of Dy substance, forming rare earth magnet of Dy/NdFeB structure.

7. Highly functional composite nanoparticles, comprising:
supports consisting of nanoparticles;
nanoparticles of second phase deposited on surfaces of the support particles by physical vapor deposition (PVD) process to enlarge surface area of the supports; and
nanoparticles of first phase deposited, by PVD process, on surfaces of the supports to which the nanoparticles of the second phase are attached.

8. The highly functional composite nanoparticles as set forth in claim 7, wherein the supports consist of carbon particles,
substance of the second phase consists of conductive ceramic substance, ITO/C structure is formed as the conductive ceramic substance in vapor state is condensed into nanoparticles on surfaces of the carbon particles,
substance of the first phase consists of platinum (Pt), and Pt-ITO/C structure catalyst for use in fuel cells is formed as the Pt in vapor state is condensed into nanoparticles on ITO/C surfaces.

9. The highly functional composite nanoparticles as set forth in claim 8, wherein the conductive ceramic substance comprises indium-tin oxide.

10. A method for producing highly functional composite nanoparticles, the method comprising:
evaporating substance of first phase by PVD process; and
condensing the evaporated substance of the first phase into nanoparticles on surfaces of supports which consist of nanoparticles.

11. The method as set forth in claim 10, wherein the supports consist of carbon particles and substance of the first phase consists of Pt substance, and Pt/C structure catalyst for use in fuel cell is formed as evaporated Pt is condensed into nanoparticles on surfaces of the carbon particles.

12. The method as set forth in claim 11, wherein the carbon particles are uniformly agitated during a process in which the evaporated Pt is condensed into the nanoparticles on the surfaces of the carbon particles.

13. The method as set forth in claim 10, wherein the PVD process consists of evaporation process which may be any of sputtering, laser, electron beam, and arc.

14. The method as set forth in claim 11, wherein the Pt is introduced into the PVD process at 1 to 10 wt % loading rate in order to form the Pt/C catalyst for use in fuel cells.

15. The method as set forth in claim 11, wherein the Pt is introduced into the PVD process at 1 to 7 wt % loading rate in order to form the Pt/C catalyst for use in fuel cells.

16. The method as set forth in claim 10, wherein the supports consist of carbon particles and substance of the first phase consists of tungsten carbide substance, and WC/C structure catalyst for use in CMP process is formed as evaporated tungsten carbide is condensed into nanoparticles on surfaces of the carbon particles.

17. The method as set forth in claim 10, wherein the supports consist of carbon particles and substance of the first phase consists of tungsten substance,
W/C structure is formed as evaporated tungsten is condensed into nanoparticles on surfaces of the carbon particles, and
WC/C structure abrasive for CMP process is formed by carburizing the W/C particles by heat treatment under reducing atmosphere.

18. A method for producing highly functional composite nanoparticles, comprising:
evaporating substance of second phase by PVD process;
forming supports to which second phase nanoparticles are attached as the evaporated substance of the second phase is condensed into nanoparticles on surfaces of the supports consisting of nanoparticles;
evaporating substance of first phase by PVD process;
condensing the evaporated substance of the first phase into nanoparticles on surfaces of the supports to which the second phase nanoparticles are attached.

19. The method as set forth in claim 18, wherein the supports consist of carbon particles,
the substance of the second phase consists of conductive ceramic substance, and ITO/C structure supports are formed as evaporated conductive ceramic substance is condensed into nanoparticles on surfaces of the carbon particles, and
the substance of the first phase consists of Pt substance, and Pt-ITO/C structure catalyst for use in fuel cells is formed as evaporated Pt is condensed into nanoparticles on surfaces of ITO/C supports.
